(19) United States
(12) Patent Application Publication
(10) Pub. No.: US 2026/0198016 A1
(43) Pub. Date: Jul. 9, 2026

(54) TUNABLE FILTER USING INTEGRATED MULTI-THROW SWITCH MATRIX

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/013,974

(22) Filed: Jan. 8, 2025

(51) Int. Cl. H03H 9/54; H03H 9/02

(52) U.S. Cl. CPC H10B 63/80; H03H 9/02; H03H 9/542

(57) ABSTRACT

The technology described herein is directed towards a tunable switched filter device including a switch matrix and selectively included or excluded fixed resonators/filters between input and output ports. Independent control of the switches of the switch matrix allows selection of different signal paths for routing a radio frequency signal from the device's input port to output port. The different signal paths can include different filters or combinations of filters, as well as a signal path that bypasses any filtering; a controller can determine which switches to open and close for each signal path. The switch matrix can be a phase change material-based (e.g., chalcogenide) radio frequency switch matrix device, in which each switch is controlled to be in either conductive (closed) or nonconductive (open) states. The tunable switched filter device can be fabricated as an ultra-compact, monolithic device that includes the switch matrix and the filters.

### BACKGROUND

In wireless communication systems, there is a demand for radio frequency (RF) filters that can operate efficiently in the sub-6 GHz frequency bands.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example tunable filter device in which tuning is achieved by controlling switches to select among different radio frequency (RF) filter paths for RF signals, in accordance with various embodiments and implementations of the subject disclosure.

FIG. 2 is a top view representation of an example tunable filter device in which tuning is achieved by individually controlling respective states of respective phase change material switches to select among different RF filter paths for RF signals, in accordance with various embodiments and implementations of the subject disclosure.

FIG. 3 is a top view representation of an example tunable filter device showing various components at different levels, in accordance with various embodiments and implementations of the subject disclosure.

FIG. 4 is a three-dimensional (3D) top perspective view representation of an example tunable filter device showing various components at different levels, in accordance with various embodiments and implementations of the subject disclosure.

FIG. 5 is a three-dimensional (3D) bottom perspective view representation of an example tunable filter device showing various components at different levels, in accordance with various embodiments and implementations of the subject disclosure.

FIG. 6 shows a representation of an example tunable filter with a general schematic representation of switches (in open states) for various selectable signal paths, in accordance with various embodiments and implementations of the subject disclosure.

FIG. 7A shows a representation of the example tunable filter with specific switches controlled to be in closed states to select a bypass signal path, in accordance with various embodiments and implementations of the subject disclosure.

FIG. 7B is a graphical representation of return loss (RL) and insertion loss (IL) for the example tunable filter corresponding to the bypass mode of FIG. 7A, in accordance with various aspects and implementations of the subject disclosure.

FIG. 8A shows a representation of the example tunable filter with specific switches controlled to be in closed states to select a signal path that includes one resonant filter (filter A), in accordance with various embodiments and implementations of the subject disclosure.

FIG. 8B is a graphical representation of example return loss (RL) and insertion loss (IL) for the example tunable filter corresponding to the filtering mode of FIG. 8A, in accordance with various aspects and implementations of the subject disclosure.

FIG. 9A shows a representation of the example tunable filter with specific switches controlled to be in closed states to select a signal path that includes another resonant filter (filter B), in accordance with various embodiments and implementations of the subject disclosure.

FIG. 9B is a graphical representation of example return loss (RL) and insertion loss (IL) for the example tunable filter corresponding to the filtering mode of FIG. 9A, in accordance with various aspects and implementations of the subject disclosure.

FIG. 10A shows a representation of the example tunable filter with specific switches controlled to be in closed states to select a signal path that includes two available resonant filters (filter A and filter B), in accordance with various embodiments and implementations of the subject disclosure.

FIG. 10B is a graphical representation of example return loss (RL) and insertion loss (IL) for the example tunable filter corresponding to the dual filtering mode of FIG. 10A, in accordance with various aspects and implementations of the subject disclosure.

FIGS. 11A, 11, 11C, 12A, 12B, 12C and 12D (example materials) show an example manufacturing process stack usable for the switch matrix, in accordance with various embodiments and implementations of the subject disclosure.

FIG. 13 is a flow diagram showing example operations related to controlling switches to select a first signal path that includes a first filter, and controlling switches to select a second signal path that includes a second filter, in accordance with various aspects and implementations of the subject disclosure.

### DETAILED DESCRIPTION

As mentioned, there is a demand for RF filters that can operate efficiently in the sub-6 GHz frequency bands. Existing solutions for tunable filters in sub-6 GHz applications primarily rely on technologies, such as coaxial, waveguide-based filters, or cavity filters, and often face challenges related to high insertion loss, limited tuning range, and complex fabrication processes, which hinder their integration into compact RF front-ends. Further, temperature variations and system vibrations can easily detune such filters.

Various implementations and embodiments of the technology described herein are generally directed towards a tunable filter based on an integrated switch matrix, such as a switch matrix based on chalcogenide phase-change materials for sub-6 GHz applications. The tunable filter, which can be fabricated as an ultra-compact device, demonstrates superior tunability, ease of integration, and consistent performance across an appropriate bandwidth.

The tunable filter can be optimized for dynamic frequency selection and reconfigurable RF systems, enabling seamless tuning across multiple frequency bands. Comprehensive simulations demonstrate high performance in the sub-6 GHz range, with low insertion loss and excellent reconfigurability. The ultra-compact design allows monolithic integration with other RF components, making it useable for applications such as 5G communication systems, adaptive RF front-ends, and frequency-agile networks.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

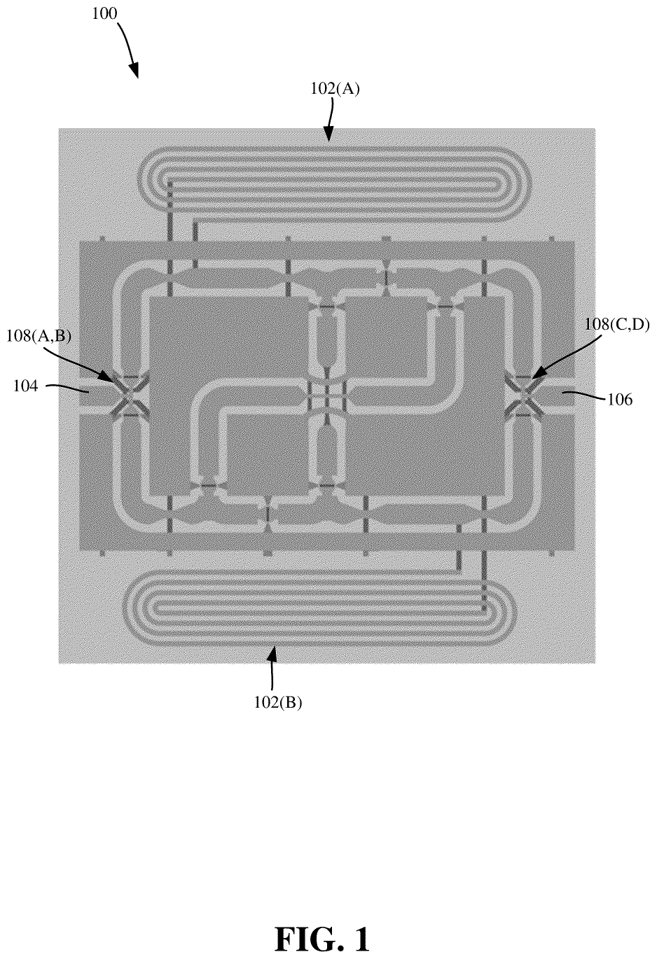

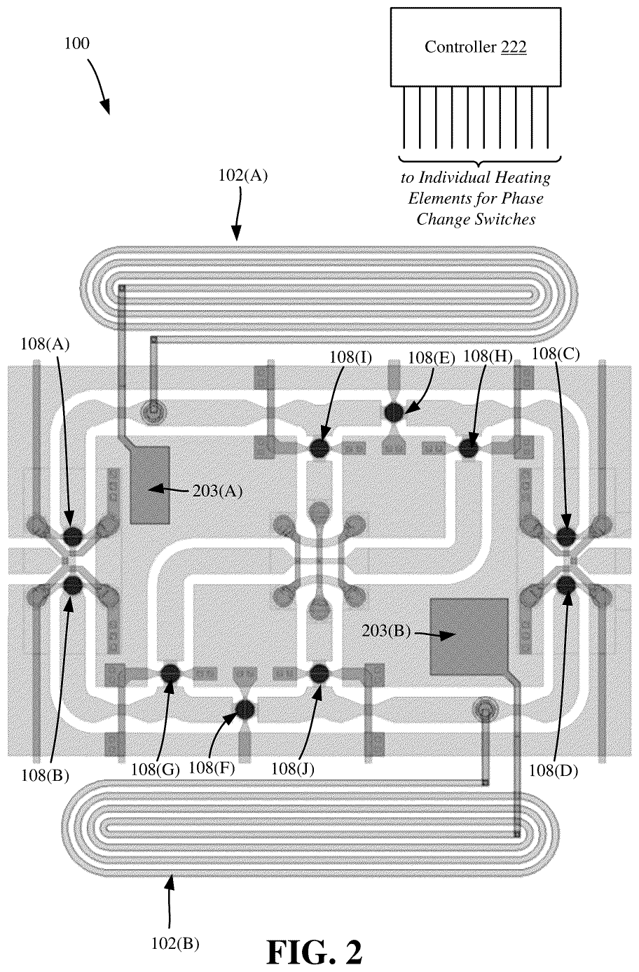

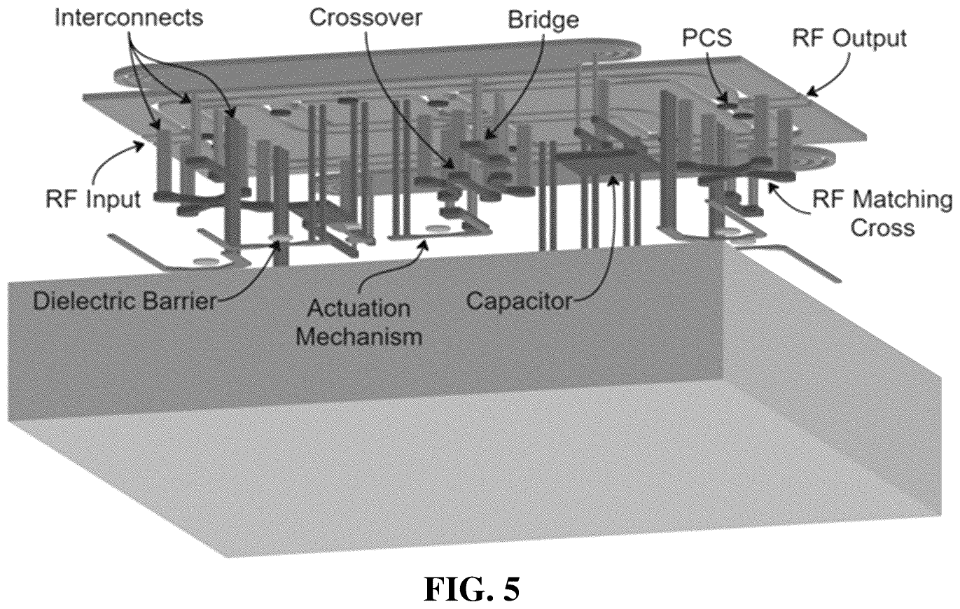

FIG. 1 shows an example top view of one implementation of a tunable filter 100 with two filters, either or both of which can be selected for filtering an RF signal obtained at an input port and directed towards an output port. As will be understood, in a bypass mode, neither filter can be used. An inductor part 102(A) of a first resonator/resonant filter is shown in FIG. 1, as is an inductor part 102(B) of a second resonator/resonant filter is shown; (the capacitor parts of the first and second resonant filters are not visible in this top view, and are depicted in FIGS. 2, 3 and 5).

Various switches of a switch matrix are controlled to select a signal path from an RF input port 104 to an RF output port 106 of the device 100. Two such switches are labeled, which in this example implementation include a splitter switch 108(A, B) with a switch pole coupled to the input port 104, and a splitter switch 108(C, D) with a switch pole coupled to the output port 106. If splitter switches are not used at the input and output side, the switch matrix can simultaneously route signals between two available ports. Note that any suitable type of RF switch can be used in the switch matrix, e.g., semiconductor, MEMS (micro-electromechanical systems) or phase change material (chalcogenide) switches; phase change material/alloy switches are described herein as a nonlimiting example.

Thus, in one implementation generally described herein, the switches of the switch matrix are phase change material (chalcogenide) switches. In addition to the separate switch elements 108(A) and 108(B) of the splitter switch 108(A, B), and elements 108(C) and 108(D) of the splitter switch 108(C, D) FIG. 1 shows eight (single-pole-single throw) switches 108(E)-108(J) are shown in FIG. 2. A controller 222 can control the switch states, which for respective phase change material switches is performed by applying a voltage (or current) pulse to respective heating elements associated with the respective switches to determine the respective conductive or nonconductive states of the respective switches 108(A)-108(J). The device 100 can include bias pads for applying voltage (or current) pulses to the individual heating elements of the heater network and thereby set the conductive or nonconductive states of the phase change material as described herein.

Turning to the phase change junctions' individual phases, in one example implementation any of the respective switches can be set to a conductive or nonconductive state. In general, with respect to heating phase change (chalcogenide) alloy material to change a junction's state from conductive (crystalline) state to nonconductive (amorphous) state and vice-versa, antimony telluride (SbTe) and germanium telluride (GeTe) are suitable phase change materials. GeSbTe can be tailored to offer more than six orders of magnitude change in material's resistivity with switching time on the order of sub-nanoseconds (ns), and thus provides more electrical contrast between the two states than SbTe, for example, (which offers up to four orders of magnitude change in material's resistance with switching time on the order of sub-picoseconds). GeSbTe also offers ultra-low resistance in crystalline state, offering better electromagnetic waves interaction and low resistive losses which are more prominent in SbTe.

Switching between the two states can be achieved by applying thermal energy such as a pulse with certain amplitude and width (duration on the order of nanoseconds (ns)) through an electrically insulated high-speed heater. Note that such phase change material holds its state as long as it is not actuated with another either crystalline or amorphous pulse, whereby the technology described herein offers energy-efficient switch reconfigurability, in that power is needed intermittently, that is, only during the reconfiguration phase when the heaters are actuated to change the state of the phase change material. Once the desired pattern is achieved, the material retains its state without the need for ongoing power.

For example, a medium amplitude and relatively longer duration (typically on the order of nanoseconds) SET electrical pulse of a heating element is used for crystallization during a transition to the ON state. Energy from the SET pulse heats the material for sufficient time to crystallize the material and provides adequate time for atoms to reorganize to an orderly arrangement, thus transforming from an amorphous state to crystalline state. To change to the amorphous state, a short duration (typically less nanoseconds than for the SET pulse) and high amplitude RESET electrical pulse is used. The RESET pulse provides sufficient energy to melt the material to disorder the atoms followed by rapid quenching to freeze the atoms, thus transforming the material from the crystalline state to the amorphous state. Significantly, only a short duration pulse to a heating element is needed to switch the state of the phase change material between states at the area/portion above the corresponding heating element; that is, the pulse transforms the material and latches the material into the state, without the need for continuous power in either state. The pulse duration and amplitude can be further optimized by tuning the ratio of GeSbTe alloy ratios.

One example implementation of the technology described herein thus uses a phase-change chalcogenide alloy in a compact switch matrix, enabling reversible switching between multiple resistance states, minimizing insertion loss, and optimizing signal routing. This facilitates tunable operation in which RF signals can be routed through any of various possible signal paths, including paths with filters, as described herein.

Also labeled in FIG. 2 are the inductor part 102(A) and a capacitor part 203(A) that together form a first filter/resonator, filter A, as described herein. Similarly labeled in FIG. 2 is the inductor part 102(B) and a capacitor part 203(B) that forms a second filter/resonator, filter B, as described herein. The result is a compact tunable filter, which in this example implementation leverages a chalcogenide-based switch matrix, enabling efficient and low-loss dynamic tuning across sub-6 GHz frequencies. The tunable filter design and layout can have the resonators/filters monolithically integrated with a circuit as a low-loss and integrated solution, (as an alternative to the inherent design complexities of tunable filters).

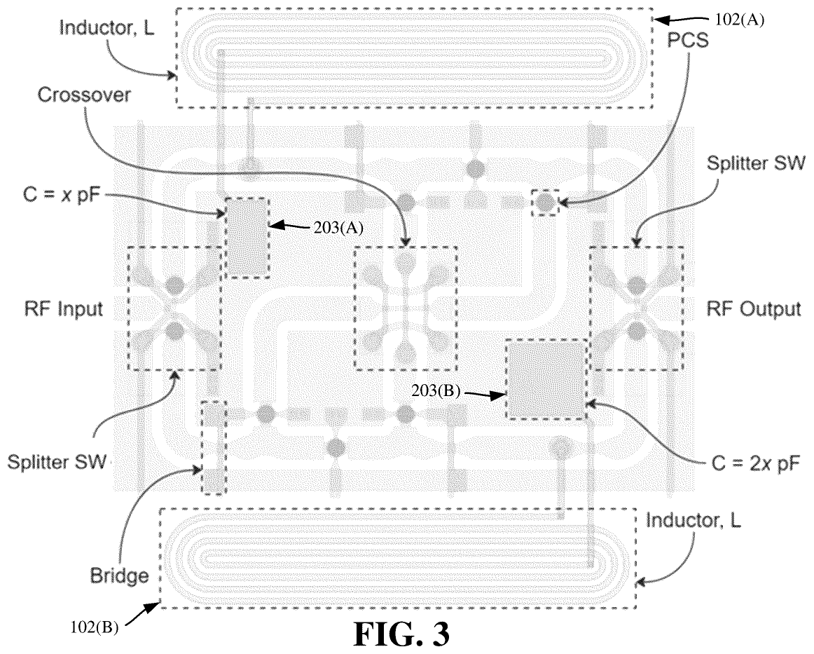

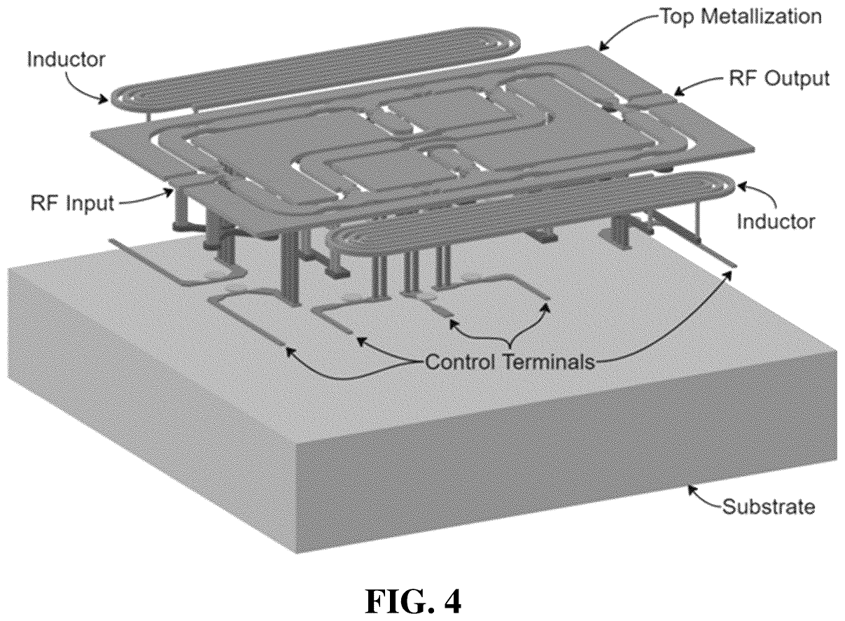

FIGS. 3-5 show additional details and components of a device 100 designed with two notch filters, with the two similar inductors 102(A) and 102(B) having the same or substantially the same inductance value. In this example, the first filter, Filter A, is designed with a series capacitor 203(A), while the second filter, Filter B, is designed with the capacitor 203(B) having double the capacitance of the first filter's capacitor 203(A) to prove the general concept using relatively widely-separated resonant frequencies. Notwithstanding, this is a nonlimiting example, as there can be more than two filters in such a device, the inductors (and/or capacitors) can be different, the device can be arranged for use as a bandpass filter instead of a notch filter, and so on.

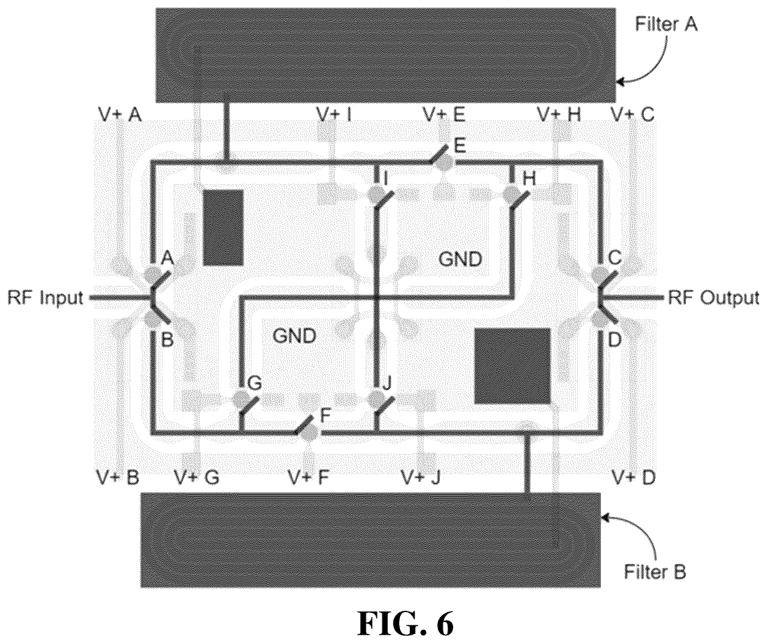

FIG. 6 shows the various respective switches A-J (for simplicity the “108” portion of the switch labels are omitted) in their open states. As such, no signal flows from the input to the output, as no path is available. FIG. 6 also shows the contact pads where voltage V+ pulses can be applied for individually heating the heating elements, generally corresponding to V+A through V+J for the respective switches A-J. note that the inductors and capacitors of the filter (Filter A) and the filter (Filter B) are shown as dark, indicating they are not operating in this state of the switches.

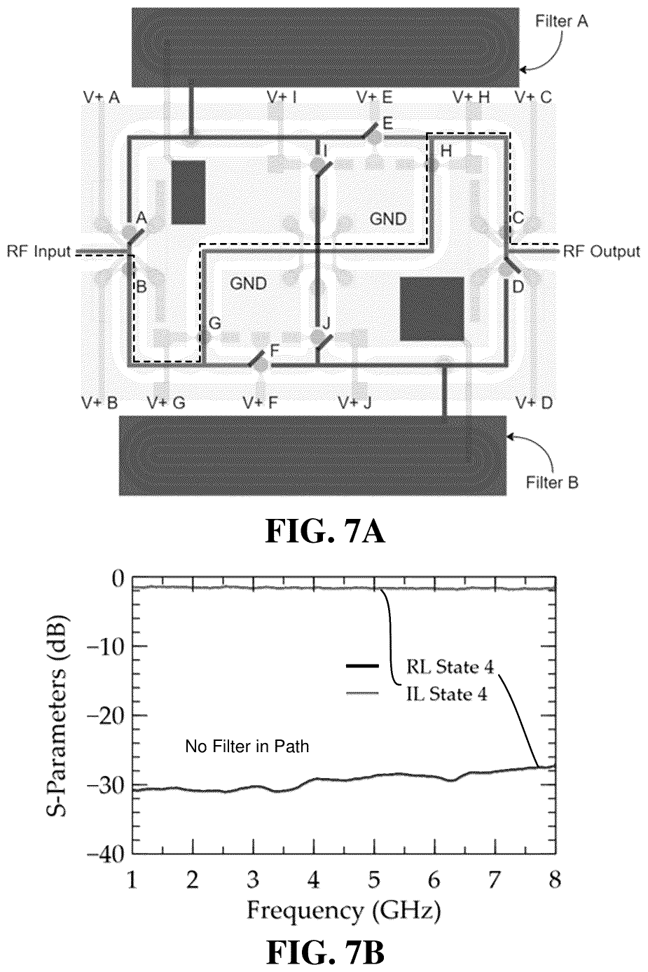

FIG. 7A shows switch states and paths for routing an RF signal at the RF input port to the RF output port. More particularly, in FIG. 7A switches B, C, G and H are activated (set to their conductive/closed states by applying the appropriate actuation voltage/pulses at their respective control terminals/contact pads; other switches are set to their nonconductive/open states). As can be seen by following the dashed line that indicates the signal path from the input port to the output port, this mode does not include any filter or other RF circuit (the inductors and capacitors of Filter A and Filter B are shown as dark) between input and output ports, and as such this operating mode can be referred to as a bypass mode (mode 1).

FIG. 7B shows the S-parameter values for return loss (RL) and insertion loss (IL) over the frequency range of 1-8 GHz.

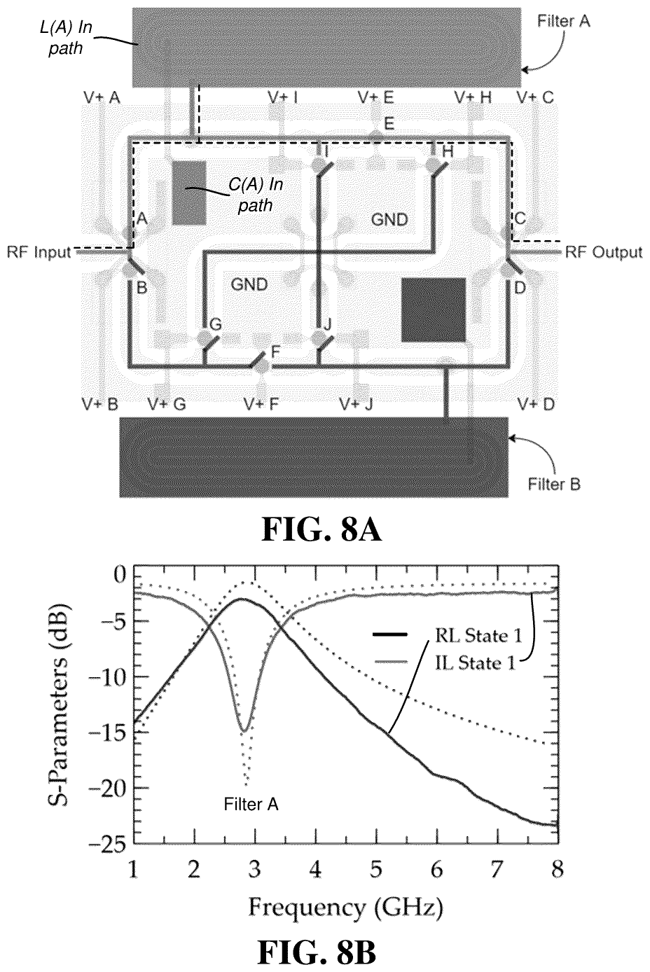

FIG. 8A shows switch states and paths for routing an RF signal at the RF input port to the RF output port. More particularly, in FIG. 8A switches A, E and C are activated (set to their conductive/closed states by applying the appropriate actuation voltage/pulses at their respective control terminals/contact pads; other switches are set to their nonconductive/open states). As can be seen by following the dashed line that indicates the signal path from the input port to the output port, this mode includes Filter A (the inductors and capacitors of Filter A are shown as lightly shaded, whereas those of Filter B are shown as dark) between input and output ports, and as such this operating mode can be referred to as a mode 2 that includes filtering by the Filter A on the signal path between the input and output ports.

FIG. 8B shows the S-parameter values for return loss (RL) and insertion loss (IL) over the frequency range of 1-8 GHz. As can be seen, significant notch filtering occurs around 3 GHz based on the inductance and capacitance values/resonant frequency of Filter A.

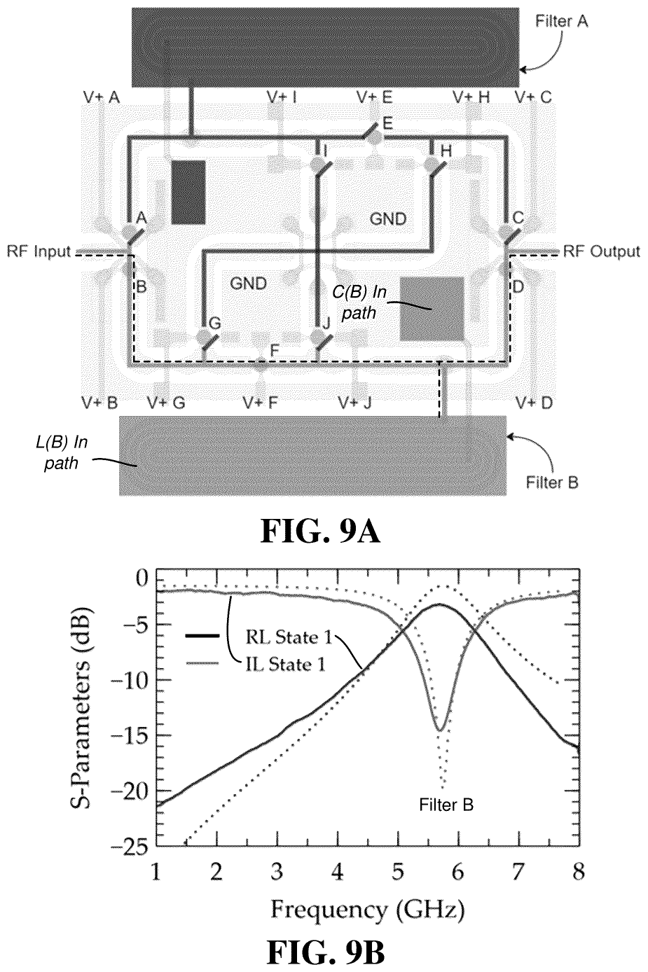

FIG. 9A shows switch states and paths for routing an RF signal at the RF input port to the RF output port. More particularly, in FIG. 9A switches B, F and D are activated (set to their conductive/closed states by applying the appropriate actuation voltage/pulses at their respective control terminals/contact pads; other switches are set to their nonconductive/open states). As can be seen by following the dashed line that indicates the signal path from the input port to the output port, this mode includes Filter B (the inductors and capacitors of Filter B are shown as lightly shaded, whereas those of Filter A are shown as dark) between input and output ports, and as such this operating mode can be referred to as a mode 3 that includes filtering by the Filter B on the signal route between the input and output ports.

FIG. 9B shows the S-parameter values for return loss (RL) and insertion loss (IL) over the frequency range of 1-8 GHz. As can be seen, significant notch filtering occurs between 5.5 and 6 GHz based on the inductance and capacitance values/resonant frequency of Filter B.

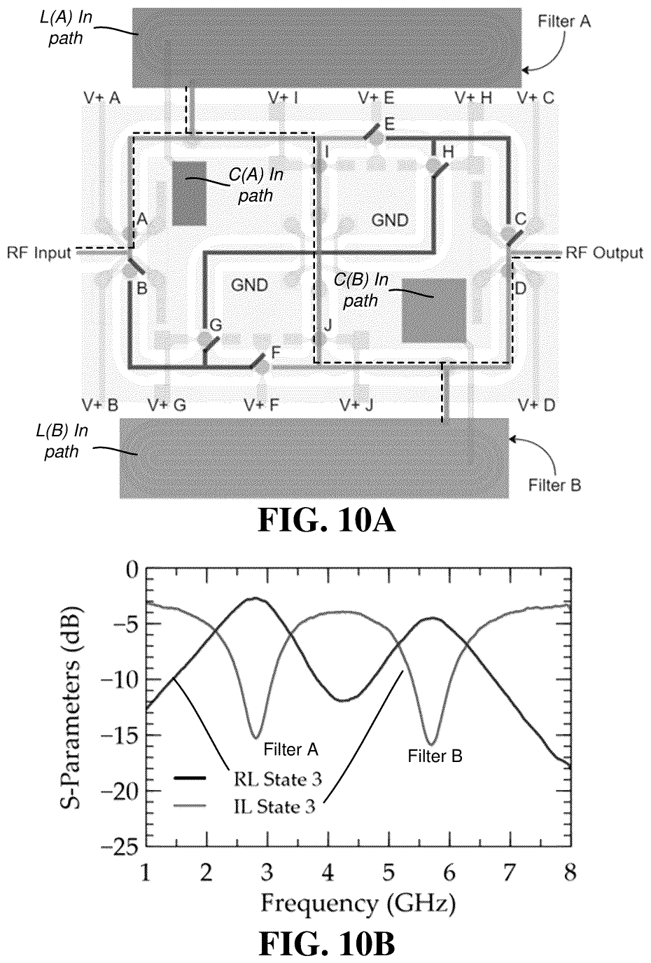

FIG. 10A shows switch states and paths for routing an RF signal at the RF input port to the RF output port. More particularly, in FIG. 10A switches A, I, J and D are activated (set to their conductive/closed states by applying the appropriate actuation voltage/pulses at their respective control terminals/contact pads; other switches are set to their nonconductive/open states). As can be seen by following the dashed line that indicates the signal path from the input port to the output port, this mode includes filter A and filter B (the inductors and capacitors of Filter A and Filter B are shown as lightly shaded) between input and output ports, and as such this operating mode can be referred to as a mode 4 that includes filtering by the Filter A and the Filter on the signal path between the input and output ports.

FIG. 10B shows the S-parameter values for return loss (RL) and insertion loss (IL) over the frequency range of 1-8 GHz. As can be seen, significant notch filtering occurs around 3 GHz based on the inductance and capacitance values/resonant frequency of Filter A, and between 5.5 and 6 GHz based on the inductance and capacitance values/resonant frequency of Filter B.

The following table, TABLE 1, summarizes the open and closed switch states for the four modes described above with reference to FIGS. 7A, 8A, 9A and 10A:

TABLE 1

| | Actuation Pulse Map | | | | | | | | | |
|---|---|---|---|---|---|---|---|---|---|---|
| Mode of Operation | V + A | V + B | V + C | V + D | V + E | V + F | V + G | V + H | V + I | V + J |
| Bypass Mode | 0 | 1 | 1 | 0 | 0 | 0 | 1 | 1 | 0 | 0 |
| Filter A in RF Path | 1 | 0 | 1 | 0 | 1 | 0 | 0 | 0 | 0 | 0 |
| Filter B in RF Path | 0 | 1 | 0 | 1 | 0 | 1 | 0 | 0 | 0 | 0 |
| Filter A + B in RF Path | 1 | 0 | 0 | 1 | 0 | 0 | 0 | 0 | 1 | 1 |

Note that only three or four switches are used per mode. This can reduce loss variation by incorporating between three to four switches used to switch between modes (with 0.1 dB of loss at less than 6 GHz, the maximum loss will not exceed 0.4 dB in any operational mode). The addition of resonators/filters to the switched tunable filter provides improved frequency selectivity and sharper roll-off characteristics. This enables the filter to precisely tune and isolate specific frequencies within the sub-6 GHz range, enhancing its performance in high-density communication environments.

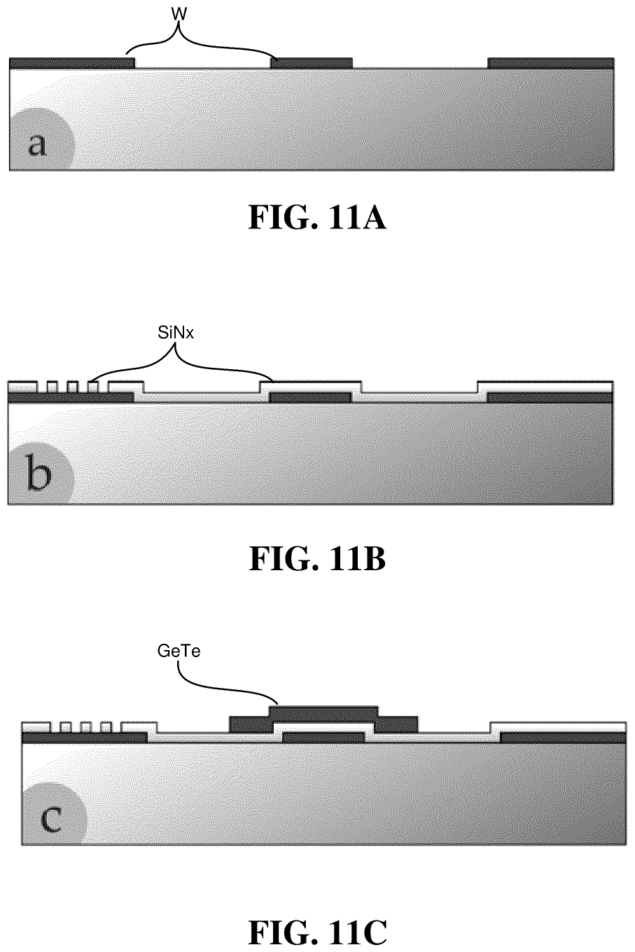

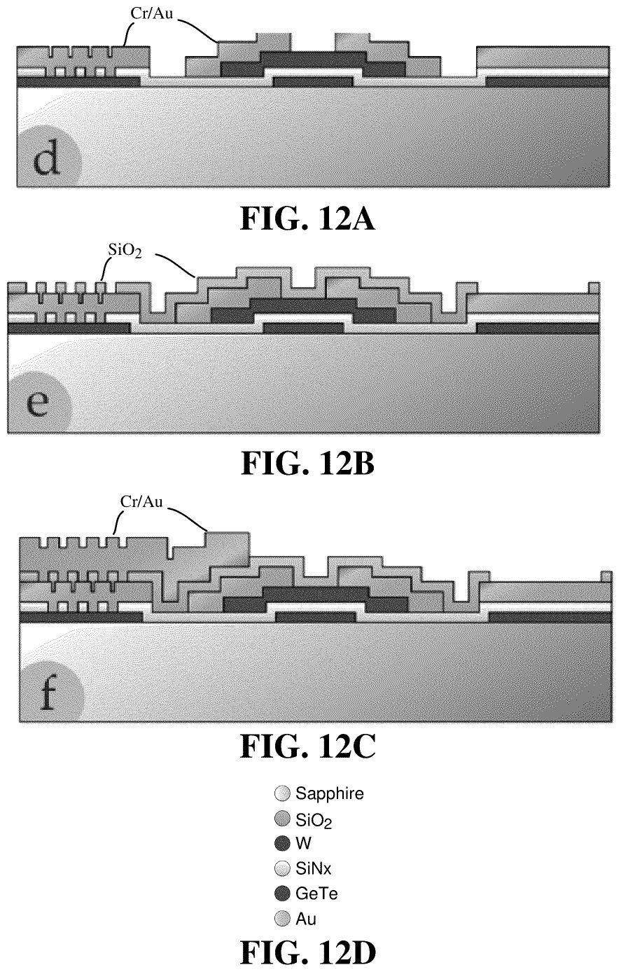

Turning to fabrication of one such tunable filter/switch matrix device, FIGS. 11A-12C, along with FIG. 12D (example materials used), show how a manufacturing process stack can be constructed, beginning with FIG. 11A which shows sputtering W (Metal_0) and patterning using reactive ion etching on a sapphire/aluminum oxide substrate in crystal form (where the “W” means wire, e.g., in the form of a thin, defined metal trace. FIG. 11B shows sputtering GeTe (phase change material) and patterning using ion milling. Next, FIG. 11C shows plasma enhanced chemical vapor deposition (PECVD) of SiO2 (silicon dioxide) (for the vias Via_1) and patterning using reactive ion etching.

FIG. 12A shows PECVD of SiNx (silicon nitride) (for the vias Via_0) and patterning using reactive ion etching. FIG. 12B shows evaporating Cr/Au (chromium/gold, Metal_1) and patterning using lift-off. FIG. 12C shows evaporating Cr/Au (Metal_2) and patterning using lift-off.

One or more implementations can be embodied in a device, including an RF input port, and an RF output port. The device can include a first RF signal path that couples a first RF resonator filter to a first RF signal obtained at the RF input port for output at the RF output port, a second RF signal path that couples a second RF resonator filter to a second RF signal obtained at the RF input port for output at the RF output port, and respective switches coupled to the RF input port and the RF output port, in which the respective switches can be controlled to determine respective open or closed states of the respective switches to select between different RF signal paths from the RF input port to the RF output port, the different RF signal paths comprising the first RF signal path and the second RF signal path.

The first resonator filter can operate with respect to a first frequency band, and the second resonator filter can operate with respect to a second frequency band that can be different from the first frequency band.

The first resonator filter can include a first inductor having a first inductance, and a first capacitor with a first capacitance, and the second resonator filter can include a second inductor with a second inductance and a second capacitance. The first inductance can be the same, or substantially the same, as the second inductance, and the first capacitance can be different from the second capacitance. The first capacitance can be the same, or substantially the same, as the second capacitance, and the first inductance can be different from the second inductance.

The different RF signal paths can include a third RF signal path without an RF resonator filter that couples a third RF signal obtained at the RF input port for output at the RF output port.

The first RF signal and the second RF signal can include a shared RF signal, and the respective switches can be controlled to route the shared RF signal via the first RF signal path and the second RF signal path to the RF output port.

The group of respective switches can include a first splitter switch including a first switch subgroup having first switch elements configured to be independently coupled to the RF input port, and a second splitter switch including second switch elements configured to be independently coupled to the RF output port.

The respective switches can include respective phase change material switches, and the device further can include a controllable heater network comprising respective heater elements associated with the respective switches; the respective heater elements can be controllable to output heat via energy pulses to selectively change respective conductive or nonconductive states of the respective switches.

Each switch of the phase change material switches can include at least one of: germanium telluride or antimony telluride.

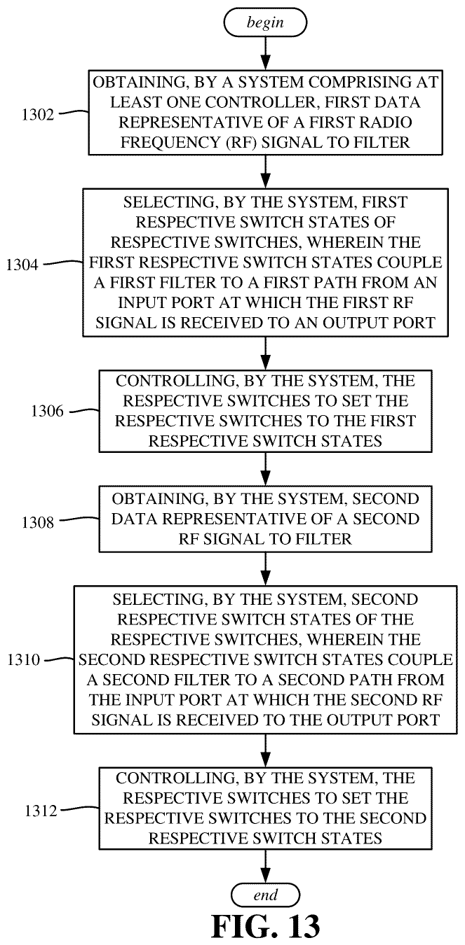

One or more example embodiments, implementations, and/or operations, such as corresponding to example operations of a method, can be represented in FIG. 13. Example operation 1302 represents obtaining, by a system comprising at least one controller, first data representative of a first radio frequency (RF) signal to filter. Example operation 1304 represents selecting, by the system, first respective switch states of respective switches, wherein the first respective switch states couple a first filter to a first path from an input port at which the first RF signal can be received to an output port. Example operation 1306 represents controlling, by the system, the respective switches to set the respective switches to the first respective switch states. Example operation 1308 represents obtaining, by the system, second data representative of a second RF signal to filter. Example operation 1310 represents selecting, by the system, second respective switch states of the respective switches, wherein the second respective switch states couple a second filter to a second path from the input port at which the second RF signal can be received to the output port. Example operation 1312 represents controlling, by the system, the respective switches to set the respective switches to the second respective switch states.

Further operations can include obtaining, by the system, third data representative of a third RF signal to filter, selecting, by the system, third respective switch states of the respective switches, wherein the third respective switch states couple a third filter to a third path from the input port, at which the third RF signal can be received, to the output port, and controlling, by the system, the respective switches to set the respective switches to the third respective switch states.

Further operations can include obtaining, by the system, third data representative of a third RF signal to which filtering can be not applicable, selecting, by the system, third respective switch states of the respective switches, wherein the third respective switch states bypass the first filter and bypass the second filter to establish a nonfiltered path from the input port, at which the third RF signal can be received, to the output port, and controlling, by the system, the respective switches to set the respective switches to the third respective switch states.

Further operations can include obtaining, by the system, third data representative of a third RF signal to filter, selecting, by the system, third respective switch states of the respective switches, wherein the third respective switch states couple the first filter to the first path from the input port at which the third RF signal can be received to the output port, and couple the second filter to the second path from the input port, at which the third RF signal can be received, to the output port, and controlling, by the system, the respective switches to set the respective switches to the third respective switch states.

The respective switches can include respective phase change material switches; controlling of the respective switches to set the respective switches to the first respective switch states can include controlling respective heating elements associated with the respective switches, in which controlling the respective heating elements can determine respective conductive or nonconductive states of the respective switches.

One or more implementations can be embodied in a tunable filter, including a multi-throw switch matrix, an RF input port coupled to the multi-throw switch matrix, and an RF output port coupled to the multi-throw switch matrix. The tunable filter can include a group of filters coupled to selectable RF signal paths from the RF input port to the RF output port, in which the multi-throw switch matrix can be controllable to select one or more of the selectable RF signal paths, for an RF signal obtained at the RF input port to the RF output port, to selectively filter the RF signal between the RF input port and the RF output port.

A first filter of the group of filters can include a first inductor and a first capacitor, a second filter of the group of filters can include a second inductor and a second capacitor, and a first capacitance value of the first capacitor can be different from a second capacitance value of the second capacitor.

A first filter of the group of filters can include a first inductor and a first capacitor, a second filter of the group of filters can include a second inductor and a second capacitor, and a first inductance value of the first inductor can be different from a second inductance value of the second inductor.

The multi-throw switch matrix can include a first splitter switch comprising a first switch subgroup having first switch elements configured for independent coupling to the RF input port, and a second splitter switch comprising second switch elements configured for independent coupling to the RF output port.

The multi-throw switch matrix can include respective phase change material switches, and the tunable filter further can include a controllable heater network including respective heater elements associated with respective switches of the multi-throw switch matrix; the respective heater elements can be controlled to output heat via energy pulses to selectively change respective conductive or nonconductive states of the respective switches.

As can be seen, the technology described herein facilitates a tunable filter device that incorporates a switch matrix to allow for dynamic routing of RF signals between the device input and output, making use of integrated tunable filters. The device can selectively pass or block specific frequency bands, making it very suitable for applications where signal routing and frequency agility are needed, such as in communication systems or phased array antennas. The switch matrix can also provide the ability to reroute signals around filters if needed, ensuring maximum flexibility in how RF paths are managed.

The tunable switched filter can be designed using an ultra-compact switch matrix and adding fixed resonators/filters in the signal path either include or exclude certain resonators/filters. Simulations demonstrate excellent performance across the sub-6 GHz spectrum, particularly in low-loss tuning applications. This approach of switching filters offer quick design to deployment, with no unnecessary filter tuning concerns (such as the need for mechanical tuning, the possibility of detuning and the like) and integration with computer-based selection of desired filter.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) input port;
an RF output port;
a first RF signal path that couples a first RF resonator filter to a first RF signal obtained at the RF input port for output at the RF output port;
a second RF signal path that couples a second RF resonator filter to a second RF signal obtained at the RF input port for output at the RF output port; and
respective switches coupled to the RF input port and the RF output port, the respective switches being controlled to determine respective open or closed states of the respective switches to select between different RF signal paths from the RF input port to the RF output port, the different RF signal paths comprising the first RF signal path and the second RF signal path.

2. The device of claim 1, wherein the first resonator filter operates with respect to a first frequency band, and wherein the second resonator filter operates with respect to a second frequency band that is different from the first frequency band.

3. The device of claim 2, wherein the first resonator filter comprises a first inductor having a first inductance, and a first capacitor with a first capacitance, and wherein the second resonator filter comprises a second inductor with a second inductance and a second capacitance.

4. The device of claim 3, wherein the first inductance is the same, or substantially the same, as the second inductance, and wherein the first capacitance is different from the second capacitance.

5. The device of claim 3, wherein the first capacitance is the same, or substantially the same, as the second capacitance, and wherein the first inductance is different from the second inductance.

6. The device of claim 1, wherein the different RF signal paths comprise a third RF signal path without an RF resonator filter that couples a third RF signal obtained at the RF input port for output at the RF output port.

7. The device of claim 1, wherein the first RF signal and the second RF signal comprise a shared RF signal, and wherein the respective switches are controlled to route the shared RF signal via the first RF signal path and the second RF signal path to the RF output port.

8. The device of claim 1, wherein the group of respective switches comprises a first splitter switch comprising a first switch subgroup having first switch elements configured to be independently coupled to the RF input port, and a second splitter switch comprising second switch elements configured to be independently coupled to the RF output port.

9. The device of claim 1, wherein the respective switches comprise respective phase change material switches, and wherein the device further comprises a controllable heater network comprising respective heater elements associated with the respective switches, the respective heater elements controllable to output heat via energy pulses to selectively change respective conductive or nonconductive states of the respective switches.

10. The device of claim 9, wherein each switch of the phase change material switches comprises at least one of: germanium telluride or antimony telluride.

11. A method, comprising:
obtaining, by a system comprising at least one controller, first data representative of a first radio frequency (RF) signal to filter;
selecting, by the system, first respective switch states of respective switches, wherein the first respective switch states couple a first filter to a first path from an input port at which the first RF signal is received to an output port;
controlling, by the system, the respective switches to set the respective switches to the first respective switch states;
obtaining, by the system, second data representative of a second RF signal to filter;
selecting, by the system, second respective switch states of the respective switches, wherein the second respective switch states couple a second filter to a second path from the input port at which the second RF signal is received to the output port; and
controlling, by the system, the respective switches to set the respective switches to the second respective switch states.

12. The method of claim 11, further comprising:
obtaining, by the system, third data representative of a third RF signal to filter;
selecting, by the system, third respective switch states of the respective switches, wherein the third respective switch states couple a third filter to a third path from the input port, at which the third RF signal is received, to the output port; and
controlling, by the system, the respective switches to set the respective switches to the third respective switch states.

13. The method of claim 11, further comprising:
obtaining, by the system, third data representative of a third RF signal to which filtering is not applicable;
selecting, by the system, third respective switch states of the respective switches, wherein the third respective switch states bypass the first filter and bypass the second filter to establish a nonfiltered path from the input port, at which the third RF signal is received, to the output port; and
controlling, by the system, the respective switches to set the respective switches to the third respective switch states.

14. The method of claim 11, further comprising obtaining, by the system, third data representative of a third RF signal to filter;
selecting, by the system, third respective switch states of the respective switches, wherein the third respective switch states couple the first filter to the first path from the input port at which the third RF signal is received to the output port, and couple the second filter to the second path from the input port, at which the third RF signal is received, to the output port; and
controlling, by the system, the respective switches to set the respective switches to the third respective switch states.

15. The method of claim 11, wherein the respective switches comprise respective phase change material switches, wherein the controlling of the respective switches to set the respective switches to the first respective switch states comprises controlling respective heating elements associated with the respective switches, and wherein the controlling of the respective heating elements determines respective conductive or nonconductive states of the respective switches.

16. A tunable filter, comprising:
a multi-throw switch matrix;
a radio frequency (RF) input port coupled to the multi-throw switch matrix;
an RF output port coupled to the multi-throw switch matrix; and
a group of filters coupled to selectable RF signal paths from the RF input port to the RF output port,
wherein the multi-throw switch matrix is controllable to select one or more of the selectable RF signal paths, for an RF signal obtained at the RF input port to the RF output port, to selectively filter the RF signal between the RF input port and the RF output port.

17. The tunable filter of claim 16, wherein a first filter of the group of filters comprises a first inductor and a first capacitor, wherein a second filter of the group of filters comprises a second inductor and a second capacitor, and wherein a first capacitance value of the first capacitor is different from a second capacitance value of the second capacitor.

18. The tunable filter of claim 16, wherein a first filter of the group of filters comprises a first inductor and a first capacitor, wherein a second filter of the group of filters comprises a second inductor and a second capacitor, and wherein a first inductance value of the first inductor is different from a second inductance value of the second inductor.

19. The tunable filter of claim 16, wherein the multi-throw switch matrix comprises a first splitter switch comprising a first switch subgroup having first switch elements configured for independent coupling to the RF input port, and a second splitter switch comprising second switch elements configured for independent coupling to the RF output port.

20. The tunable filter of claim 16, wherein the multi-throw switch matrix comprises respective phase change material switches, and wherein the tunable filter further comprises a controllable heater network comprising respective heater elements associated with respective switches of the multi-throw switch matrix, the respective heater elements controlled to output heat via energy pulses to selectively change respective conductive or nonconductive states of the respective switches.
